(19) United States
(12) Patent Application Publication
(10) Pub. No.: US 2010/0294549 A1
(43) Pub. Date: Nov. 25, 2010

(54) METHOD FOR MAKING A COMPONENT HAVING AN ELECTRONIC FUNCTION

(75) Inventors: Henri Laville, Lagny Sur Marne (FR); Arnaud Langle, Pontault Combault (FR); Rémi Noguéra, Limoges (FR)

Correspondence Address: HARNESS, DICKEY & PIERCE, P.L.C., P.O. BOX 828, BLOOMFIELD HILLS, MI, 48303, US

(73) Assignees: EROFARAD - EFD, Chanteloup En Brie (FR); CERADROP, Limoges (FR)

(21) Appl. No.: 12/742,565

(22) PCT Filed: Nov. 12, 2008
(86) PCT No.: PCT/FR2008/001590

§ 371 Date: Aug. 10, 2010

(30) Foreign Application Priority Data
Nov. 13, 2007 (FR) 0707976

(51) Int. Cl. H05K 1/00; B05D 5/12; H05K 1/16

(52) U.S. Cl. 174/258; 427/79; 174/260

(57) ABSTRACT

The disclosure relates to a method for making multi-material three-dimensional components providing a mechanical link between thin layers. To this end, the disclosure provides a method for making a multi-material three-dimensional component that includes at least first and second materials. The method includes making at least two superimposed printed layers along discrete space routes of a printing travel, the printed layers being made by the contactless deposition of localised impacts of printing droplets, and a homogenous printed layer includes at least the first material, with the second material being excluded, while at least one mixed printed layer includes the first material, and at least the second material.

### CROSS-REFERENCE TO RELATED APPLICATIONS

This application is a National Phase Entry of International Application No. PCT/FR2008/001590, filed on Nov. 12, 2008, which claims priority to French Application 0707976, filed on Nov. 13, 2007, both of which are incorporated by reference herein.

### BACKGROUND AND SUMMARY

The present invention relates to the methods for making components having electronic functions. The invention more particularly, but not exclusively relates, to a method for making capacitors.

Various methods are known for making components having electronic functions. The most conventional technique for making capacitors based on ceramic materials consists in making various sheets of ceramic material using any appropriate technique, for example casting, silkscreen deposition or any other equivalent technique, stacking the sheets of ceramic material thus obtained, submitting the stacking to a thermo-compression, then cutting the assembly thus obtained to form capacitor units. Other techniques, aiming at reducing the number of operating steps, have been experienced or used with, sometimes, as was the case with the well-known technique of the wet process, significant results. But no technique makes it possible to optimise the anchoring of ceramic layers together.

A method for making multi-material three-dimensional components by depositing ink jets is more particularly known and described, for example in the document FR-A-2859128. This document discloses a method for depositing successive printed layers of ceramic and metallic materials. This method further introduces, as indicated in page 16, lines 22 to 26, for a given layer, a surface condition with some roughness so as to influence the arrangement, as regards the spreading and the dispersion of the material which will then be deposited on this layer.

Theoretically, such a method should make it possible to improve the manufacture cost-effectiveness and the performance of the obtained products. As a matter of fact, this method more particularly makes it possible to optimise an important characteristic of the component, i.e. isotropy, so as to obtain an improved cohesion of the component and to increase the mechanical resistance thereof, as indicated in the document FR-A-2859128, page 17, lines 25 to 34. However, today, the implementation of the method described in the document FR-A-2859128 for making components having an electronic function is not always totally satisfactory.

Another method for making passive electronic components by depositing ink jets is also known and described in the document WO 2006/076607 A1. This document provides to use an ink selected for the adherence and thermal expansion coefficients so as to provide stability and compatibility of such ink with other inks which shall be used for making other printed layers, as indicated in the document WO 2006/076607 A1, page 8, paragraph [0033]. Now, this method is not totally satisfactory as regards the linking between the printed layers.

One object of the present invention is to provide a method for making multi-material three-dimensional components solving the above-mentioned drawbacks of the prior art. To this end, the invention provides a method for making a multi-material three-dimensional component including at least a first and a second material. The method consists in making at least two superimposed printed layers along discrete space routes of a printing travel, the printed layers being made by the contactless deposition of localised impacts of printing droplets, and:

a homogenous printed layer NA is composed of at least the first material, with the second material being excluded, and

at least a mixed printed layer NI is composed of the first material and at least the second material.

Preferably, at least another mixed printed N_{I+1} is superimposed onto the previous mixed printed layer N_{I}. Advantageously, the first material of the mixed printed layer N_{I+1} is substantially superimposed onto the first material of the previous mixed printed layer N_{I}. Preferably, a plurality of mixed printed layers is successively deposited thus forming a first mixed thin layer M_{I} having complementary reliefs for linking the first and second materials.

Advantageously, a plurality of homogenous printed layers N_{A} composed of at least the first material, with the second material being excluded and forming a homogenous thin layer M_{A}, is successively deposited onto the first mixed thin layer M_{I}. Alternatively, a plurality of homogenous layers N_{B} composed of at least the second material, with the first material being excluding and forming a homogenous thin layer M_{B}, is successively deposited onto the first mixed thin layer M_{I}. Preferably, at least two other thin layers, a mixed one M_{I} then a homogenous one M_{A}; M_{B}, are successively deposited onto the previous homogenous layer M_{A}; M_{B}.

According to particular exemplary embodiments:

at least one of the complementary reliefs of the first and second materials has the shape of a dome;

at least one of the complementary reliefs forms a bushing between two homogenous thin layers;

the projected printing droplets have at least one component in liquid phase and at least one component in solid phase so as to form a liquid mixture;

the volume proportion of the element in solid phase within the liquid mixture is contained between 1% and 50%;

the viscosity of the projected liquid mixture is contained between 1 and 40 mPa·s;

the surface tension of the projected liquid mixture is contained between 20 and 70 mN/m;

the positions are executed on a support made of an evanescent material, for example based on graphite or paper, liable to be destroyed at a high temperature;

at least one of the deposited materials is based on ceramic material;

the method can be applied to the manufacturing of capacitors, capacitive resistive multi-functional, capacitive inductive and capacitive inductive resistive components.

According to another aspect, the invention also relates to a multi-material three-dimensional component liable to be obtained by implementing the method according to any one of the above-mentioned methods. The component includes at least two printed layers executed by the contactless depositing of localised impact of printing droplets, and:

a homogenous printed layer NA includes at least a first material, with a second material being excluded, and

at least a mixed printed layer NI includes the first of at least a second material.

Advantageously, the component further includes at least one mixed printed layer N_{I+1} superimposed onto the printed layer N_{I}. Preferably, the first material of the printed layer N_{I+1} is substantially superimposed onto the first material of the previous printed layer N_{I}. Advantageously, the component includes a plurality of mixed printed layers forming a mixed thin layer M_{I} showing complementary reliefs of the first and second materials.

Preferably, it includes a plurality of homogenous printed layers N_{A}, composed of at least the first material, with the second material being excluded and forming a homogenous thin layer M_{A}, successively deposited onto the first mixed thin layer M_{I}. Alternatively, it includes a plurality of homogenous printed layers N_{B} composed of at least the second material, with the first material being excluded and forming a homogenous thin layer M_{B}, successively deposited onto the first mixed thin layer M_{I}. Advantageously, it includes at least two other thin layers, a mixed one M_{I} then a homogenous one M_{A}; M_{B}, successively deposited onto the previous homogenous thin layer M_{A}; M_{B}.

According to advantageous exemplary embodiments:

at least one of the complementary reliefs has the shape of a dome;

at least one of the complementary reliefs forms a bushing between two homogenous thin layers MA; MB;

at least one of the materials deposited is based on ceramic material.

The invention finally relates to a multi-functional capacitive resistive, capacitive inductive and capacitive inductive resistive component according to any one of the above-mentioned exemplary embodiments. As will be explained in greater details in the following, the method for making the component and the component according to the invention make it possible to improve the mechanical behaviour or linking between the various thin layers forming the component. More particularly, stacking alternatively mixed and homogenous printed layers makes it possible to provide the mechanical linking between the thin layers.

Obtaining complementary reliefs of the first and second materials having the shape of a dome makes it possible to link several homogenous thin layers without affecting the conductivity of the component. In addition, the complementary relief forming a bushing between two homogenous thin layers substantially improves the mechanical behaviour between such two homogenous thin layers. Printed layer means an elementary thickness of a localised deposition of printing droplets obtained along a discrete space route and forming a continuum. Thus, two printing droplets forming the same printed layer are not considered as superimposed if they are only partially overlapping. On the contrary, superimposed printed layers means the successive deposition of at least two printed layers along a constant direction which is substantially perpendicular to the deposition surface.

In addition, homogenous printed layer means a printed layer formed by the deposition of at least a first material, with a second material being excluded or the deposition of at least the second material, with the first material being excluded. On the contrary, mixed printed layer means a printed layer using at least the first and the second materials. Similarly, homogenous thin layer means the superimposition of at least two homogenous printed layers and mixed thin layer means the superimposition of at least two mixed printed layers.

### BRIEF DESCRIPTION OF THE DRAWINGS

Other characteristics, objects and advantages of the present invention will appear upon reading the following description of detailed exemplary embodiments given as non-limitative examples, wherein:

FIG. 1 shows a schematic cross-sectional view of two superimposed homogenous and mixed printed layers according to one embodiment according to the invention;

FIGS. 2a and 2b show three superimposed printed layers according to one embodiment according to the invention;

FIGS. 3, 4, 5 and 6 show cross-sectional views of five superimposed thin layers according to one embodiment according to the invention and for which several complementary reliefs of the first and second materials have the shape of a dome; and

FIG. 7 shows a cross-sectional view of three superimposed thin layers according to one embodiment according to the invention and for which several complementary reliefs of the first and second materials form a bushing between two homogenous thin layers.

### DETAILED DESCRIPTION

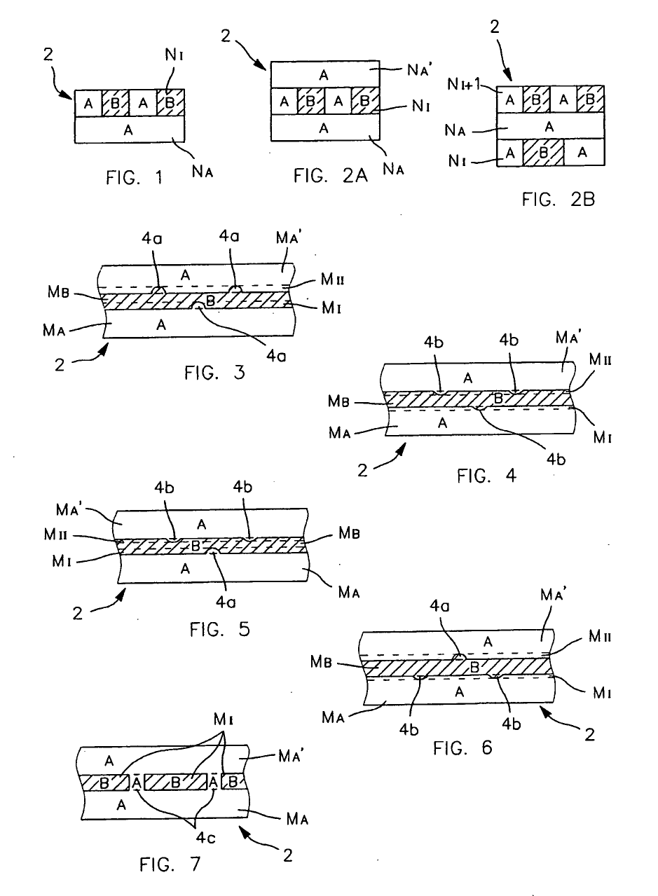

One embodiment of a multi-material three-dimensional component 2 according to the invention will now be explained in details while referring to FIG. 1. In this exemplary embodiment, the multi-material three-dimensional component 2 is obtained by the contactless deposition of localised impacts of printing droplets according to a discrete space route of a printing travel. The localised impacts of printing droplets form firstly a homogenous printed layer N_{A} composed of a first material A. Secondly, the localised impacts of printing droplets form a mixed printed layer N_{I} composed of the first material A and a second different material B.

The ceramic materials used within the scope of the present invention can be the subject of many alternative embodiments known to the persons skilled in the art. Thus, they shall not be disclosed in details in the following.

Similarly, FIGS. 2a and 2b schematically show two exemplary embodiments of components 2 according to the present invention. In FIG. 2a, the component 2 includes a first homogenous printed layer N_{A} whereon a mixed printed layer N_{I} and a second homogenous printed layer N_{A′} are superimposed. In FIG. 2b, the component 2 includes a first mixed printed layer N_{I} whereon a homogenous printed layer N_{A} then a second mixed printed layer N_{I+1} are superimposed. In practice, the finally obtained component 2 according to the invention preferably includes a larger number of printed layers N_{A}, N_{B}, N_{I}, N_{I+1} formed according to the production method according to the invention.

According to another aspect, the method for making a component according to the invention makes it possible to make a component 2 having at least two thin layers M_{A}, M_{B}, M_{I}, M_{II}, each being composed of a plurality of superimposed printed layers N_{A}, N_{B}, N_{I}, N_{II+1}. A thin layer formed by superimposing a plurality of homogenous printed layers N_{A}, N_{B} is called a homogenous thin layer M_{A}, M_{B}. On the contrary, a thin layer formed by the superimposition of a plurality of mixed printed layers N_{I}, N_{I+1} is called a mixed thin layer M_{I}; M_{II}.

According to a preferred exemplary embodiment, the first material A of a mixed printed layer N_{I+1} is substantially superimposed onto the first material A of the previous mixed printed layer N_{I} so as to form a mixed thin layer M_{I}; M_{I+1}, showing complementary reliefs of the first and second materials A, B. Such complementary reliefs provide a linking between the various thin layers of the component 2. Then, it is not a surface condition provided with some roughness making it possible to increase the mechanical resistance of the component 2, but real reliefs preventing the relative displacement of two superimposed homogenous thin layers.

Such an exemplary embodiment will now be described while referring to FIGS. 3 to 6. In such an exemplary embodiment, a first homogenous thin layer M_{A} is executed by the successive deposition of a plurality of homogenous printed layers. A first mixed thin layer M_{I} is then superimposed onto the first homogenous thin layer M_{A}. The first thin layer M_{I} has complementary reliefs 4 of the first and second materials (A, B).

A second homogenous thin layer M_{B} is then superimposed onto the previous mixed thin layer M_{I}. The persons skilled in the art will easily understand that the reliefs thus formed between the first homogenous thin layer M_{A} and the second homogenous thin layer M_{B} make it possible to improve the mechanical linking of such homogenous thin layers M_{A}, M_{B} and consequently the cohesion of the final component 2. Then, a second mixed thin layer M_{II} will also having complementary reliefs 4, then a third homogenous thin layer M_{A′} are successively superimposed onto the second homogenous thin layer M_{B}.

The above-mentioned reliefs 4 can be the subject of several alternative embodiments of the invention. These can be protruding reliefs 4a such as shown in FIG. 3, or recessed reliefs 4b such as shown in FIG. 4. This can also be a combination of protruding reliefs 4a and recessed reliefs 4b, as illustrated in FIGS. 5 and 6.

According to a preferred exemplary embodiment described while referring to FIG. 7, the component 2 shows a first homogenous thin layer M_{A} whereon a mixed thin layer M_{I} then a second homogenous thin layer M_{A′} are superimposed. In this exemplary embodiment, the first and second homogenous thin layers M_{A}, M_{A′} are both formed from at least a first material A, with a second material B being excluded. Then, the complementary reliefs 4 form bushings 4c of the first material A between the first and second homogenous thin layers M_{A}, M_{A′}. Generally, such bushings 4C composed of the material A are formed locally in a mixed thin layer also including a different material B, so as to link at least two printed layers N_{A}, N_{A′} composed of at least the same material A, with the second material B being excluded.

The successive depositions of printed layers within the scope of the present invention can be performed with any technique known to the persons skilled in the art. This technique is preferably an ink jet deposition. In this context, the applicant determined that various parameters of deposited inks are decisive to obtain a functional and liable component 2.

First, the projected droplets are composed of at least one component in solid phase and one component in liquid phase so as to form a liquid mixture. Preferably, the volume proportion of mineral filler in the deposited inks is substantially contained between 1 and 50%. In addition, preferably, the viscosity of the deposited inks is contained between approximately 1 and approximately 40 mPa·s. Then, the applicant determined that the surface tension of the deposited inks is contained between approximately 20 and approximately 70 mN/m. The ink jet deposition of the layer forming the component 2 according to the present invention can be executed on any appropriate support.

According to an advantageous alternative embodiment making it possible to prevent any difficulty in separating the component 2 and the above-mentioned support receiving the printed layers N_{A}, N_{B}, N_{I}, N_{I+1} through ink jets because of an intrinsic porosity of the support, such support is formed of an evanescent material. This means that the material is intended to be suppressed by any appropriate technique once the component 2 or at least the first printed layer N_{A}, N_{B}, N_{I} is provided. More precisely, within the scope of the present invention, to this end, the supporting layer receiving the ink jet disposition is formed of a material liable to be destroyed at a high temperature, for example based on graphite or paper of any appropriate composition.

Preferably but not limitatively, within the scope of the exemplary embodiments shown in FIGS. 1, 2a and 2b, the mixed printed layers N_{I}, N_{I+1} integrate electrically conductive fillers, whereas the homogenous printed layers N_{A}, N_{A′} are layers made of an electrically isolating material. In this context, the mixed printed layers N_{I}, N_{I+1} form, for example, the plates of the capacitors.

However, the present invention is not limited to the execution of components 2 of the capacitor type. It concerns the making of any type of component 2 having an electronic function, for example components 2 integrating resistive and/or inductive functions through the use of resistive or inductive ink on localised pads. The present invention also makes it possible to provide, as alternative solutions, multi-functional RC (resistive and capacitive), LC (inductive and capacitive) or RLC (resistive, inductive and capacitive) components 2.

Of course, the present invention is not limited to the embodiments discussed here-above but can be extended to any alternative which can be executed by the persons skilled in the art. Therefore, the present invention is not limited to the particular embodiment of capacitors but on the contrary it concerns the manufacturing of numerous other components 2 having an electronic function, such as for example components 2 integrating resistive and/or inductive elements. In addition, some mixed thin layers (not shown) can be formed from randomly superimposed mixed printed layers so that the materials A and B are mixed within such mixed thin layers.

1. A method for making a multi-material three-dimensional component comprising at least a first and a second material, the method comprising:
making at least two superimposed printing layers along discrete space routes of a printing travel, the printed layers being made by the contactless deposition of localised impacts of printing droplets forming a homogenous printed layer comprising at least the first material, with the second material being excluded, or at least one mixed printed layer comprising the first material and at least the second material;
superimposing at least another mixed printed layer on the previous mixed printed layer, the first material of the mixed printed layer being substantially superimposed onto the first material of the previous mixed printed layer; and
successively depositing a plurality of mixed printed layers thus forming a first mixed thin layer having complementary reliefs for linking the first and second materials.

2. A method for making a component according to claim 1, further comprising a plurality of homogenous printed layers comprising at least the first material, with the second material being excluded and forming a homogenous thin layer, being successively deposited onto the first mixed thin layer.

3. A method for making a component according to claim 1, further comprising a plurality of homogenous printed layers comprising at least the second material, with the first material being excluded and forming a homogenous thin layer, being successively deposited onto the first mixed thin layer.

4. A method for making a component according to claim 1, further comprising at least two other thin layers, a mixed one then a homogenous one, being successively deposited onto the previous homogenous thin layer.

5. A method according to claim 1, wherein at least one of the complementary reliefs for linking the first and second materials have the shape of a dome.

6. A method according to claim 1, wherein at least one of the complementary reliefs makes a bushing through two homogenous thin layers.

7. A method according to claim 1, wherein the projected printing droplets have at least one component in liquid phase and at least one component in solid phase so as to make a liquid mixture.

8. A method according to claim 1, wherein the volume proportion of the element in solid phase within the liquid mixture is contained between 1% and 50%.

9. A method according to claim 1, wherein the viscosity of the projected liquid mixture is contained between 1 and 40 mPa·s.

10. A method according to claim 1, wherein the surface tension of the projected liquid mixture is contained between 20 and 70 mN/m.

11. A method according to claim 1, wherein the depositions are executed on a support made of evanescent material liable to be destroyed at a high temperature.

12. A method according to claim 1, further comprising applying it upon the manufacturing of capacitors, multi-functional capacitive resistive, capacitive inductive and capacitive inductive resistive components.

13. A method according to claim 1, wherein at least one of the deposited materials is based on ceramic material.

14. A multi-material three-dimensional component comprising:
at least two printed layers executed through the contactless deposition of localised impacts of printing droplets forming a homogenous printing layer comprising at least a first material, a second material being excluded, and at least one mixed printing layer comprising the first material and at least the second material;
the component further comprising at least one mixed printing layer superimposed on the printed layer, the first material of the printed layer being substantially superimposed on the first material of the previous printed layer; and
a plurality of mixed printed layers forming a mixed thin layer having complementary reliefs for linking the first and second materials.

15. A component according to claim 14, further comprising a plurality of homogenous printed layers comprising at least the first material, with the second material being excluded and forming a homogenous thin layer successively deposited on the first mixed thin layer.

16. A component according to claim 14, further comprising a plurality of homogenous printed layers comprising at least the second material, with the first material being excluded and forming a homogenous thin layer, successively deposited on the first mixed thin layer.

17. A component according to claim 15, further comprising at least two other thin layers, a mixed one then a homogenous one successively deposited on the previous homogenous thin layer.

18. A component according to claim 14, wherein at least one of the complementary reliefs has the shape of a dome.

19. A component according to claim 14, wherein at least one of the complementary reliefs forms a bushing between two homogenous thin layers.

20. A component according to claim 14, wherein at least one of the deposited materials is based on ceramic material.

21. A capacitor or a multi-functional capacitive resistive, capacitive inductive and capacitive inductive resistive component according to claim 14.
